(19) United States
(12) Patent Application Publication
(10) Pub. No.: US 2013/0076543 A1
(43) Pub. Date: Mar. 28, 2013

(54) Decoding Method for Biphase-Encoded Data

(71) Applicants: Xian-Feng Yang, Fuqing City (CN); Xiao-Qin Guo, Fuqing City (CN)

(72) Inventors: Xian-Feng Yang, Fuqing City (CN); Xiao-Qin Guo, Fuqing City (CN)

(21) Appl. No.: 13/239,699

(22) Filed: Sep. 22, 2011

(51) Int. Cl. H03M 7/12

(52) U.S. Cl. 341/70

(57) ABSTRACT

A decoding method for biphase-encoded data is provided. The decoding method includes detecting falling-edge transitions in the biphase-encoded data to decode according to a time difference (Δt) between each two adjacent falling-edge transitions and the logic value of previous bit. When Δt is 1 bit period and previous bit is logic 1, it's determined that present bit is logic 1. When Δt is 1 bit period and previous bit is logic 0, it's determined that present bit is logic 0. When Δt is 1.5 bit periods and previous bit is logic 1, it's determined that present and next bits are both logic 0. When Δt is 1.5 bit periods and previous bit is logic 0, it's determined that present bit is logic 1. When Δt is 2 bit periods and previous bit is logic 1, it's determined that present and next bits are logic 0 and 1 respectively.

### BACKGROUND OF THE INVENTION

1. Field of the Invention

The present invention relates to a decoding method for biphase-encoded data and, more particularly, to a decoding method for biphase-encoded data by detecting specific transitions in the biphase-encoded data and decoding the biphase-encoded data according to a time difference between each two adjacent specific transitions.

2. Description of the Related Art

A remote control system includes a transmitter end and a receiver end. The transmitter end such as a remote controller transmits a command from a distance to the receiver end such as a television, in which the command is used to indicate a specific function that the receiver end is to perform. The receiver end receives and recognizes the received command in order to perform the specific function is upon the received command. It needs a transmission protocol for handling communication between the transmitter end and the receiver end. The RC-5 protocol is a transmission protocol for infrared (IR) remote control. According to the RC-5 protocol, the transmitter end transmits a modulated IR signal carrying a Manchester-encoded command, and the receiver end receives, demodulates, samples and decodes the modulated IR signal to reconstruct the Manchester-encoded command in order to perform the specific function upon the received command. It is known that Manchester encoding is a type of biphase encoding so that the Manchester-encoded command is a type of biphase-encoded data.

Now there exist several decoding methods for the biphase-encoded data. One commonly used decoding method includes using additional decoder chip, but it needs higher cost. Another commonly used decoding method includes sampling levels of waveform of the biphase-encoded data per a constant time period, but it has poor anti-interference so as to increase decoding error probability. Still another commonly used decoding method includes counting to obtain the periods of high and low levels of waveform of the biphase-encoded data and determining the order of the high and low levels, but it needs to count time and determine the order so as to occupy more system resources and increase the difficulty in software implementation.

### SUMMARY OF THE INVENTION

The present invention is directed to providing a decoding method for biphase-encoded data capable of using no additional decoder chip, occupying less system resources, having good anti-interference and reducing the difficulty in software implementation.

According to one aspect of the present invention, there is provided a decoding method for biphase-encoded data having a plurality of bits, in which the logic value of a first bit of the bits is known. When one of the bits has a transition from a first level to a second level at a time within a bit period, the logic value of the one of the bits is defined to be a first logic value. When one of the bits has a transition from the second level to the first level at the time within the bit period, the logic value of the one of the bits is defined to be a second logic value.

The decoding method for the biphase-encoded data includes detecting specific transitions in the biphase-encoded data to obtain a time difference between each two adjacent specific transitions. When the time difference is 1 bit period and the logic value of a previous bit is the first logic value, it's determined that the logic value of a present bit is the first logic value. When the time difference is 1 bit period and the logic value of a previous bit is the second logic value, it's determined that the logic value of a present bit is the second logic value. When the time difference is 1.5 bit periods and the logic value of a previous bit is the first logic value, it's determined that the logic values of a present bit and a next bit are both the second logic value. When the time difference is 1.5 bit periods and the logic value of a previous bit is the second logic value, it's determined that the logic value of a present bit is the first logic value. When the time difference is 2 bit periods and the logic value of a previous bit is the first logic value, it's determined that the logic values of a present bit and a next bit are the second logic value and the first logic value, respectively.

In one embodiment of the present invention, the biphase-encoded data may be Manchester-encoded data.

In one embodiment of the present invention, the first level may be higher than the second level; in other words, the first level is a high level and the second level is a low level. In another embodiment of the present invention, the first level may be lower than the second level; in other words, the first level is a low level and the second level is a high level.

In one embodiment of the present invention, the first logic value and the second logic value may be logic 1 and logic 0 respectively. In another embodiment of the present invention, the first logic value and the second logic value may be logic 0 and logic 1 respectively.

In one embodiment of the present invention, the specific transition may be the transition from the first level to the second level. In another embodiment of the present invention, the specific transition may be the transition from the second level to the first level.

In one embodiment of the present invention, the biphase-encoded data may be applied to remote control encoded data using an RC-5 protocol. In another is embodiment of the present invention, the biphase-encoded data may be applied to remote control encoded data using an extended RC-5 protocol.

The present invention detects specific transitions in the biphase-encoded data to decode the biphase-encoded data according to a time difference between each two adjacent falling-edge transitions and the logic value of previous bit so that it uses no additional decoder chip, occupies less system resources, has good anti-interference and is easy to implement in software.

### BRIEF DESCRIPTION OF THE DRAWINGS

The foregoing and other features of the disclosure will be apparent and easily understood from a further reading of the specification, claims and by reference to the accompanying drawings in which:

FIG. 1 is an exemplary diagram illustrating several partial waveforms of Manchester-encoded data;

FIG. 2 is a flowchart illustrating a decoding method for Manchester-encoded data according to an embodiment of the present invention; and

FIG. 3 is an exemplary diagram illustrating the decoding process of Manchester-encoded data using the decoding method shown in FIG. 2.

### DETAILED DESCRIPTION OF THE INVENTION

In the following exemplary embodiments, biphase-encoded data is Manchester-encoded data, a first level and a second level are a high level and a low level respectively, a first logic value and a second logic value are logic 1 and logic 0 respectively, a specific transition is a transition from the first level to the second level and accordingly the specific transition is a transition from the high level to the low level (i.e. a falling-edge transition), but the present invention is not limited thereto. For example, the first logic value and the second logic value may be logic 0 and logic 1 respectively, or the specific transition may be a transition from the low level to the high level (i.e. a rising-edge transition).

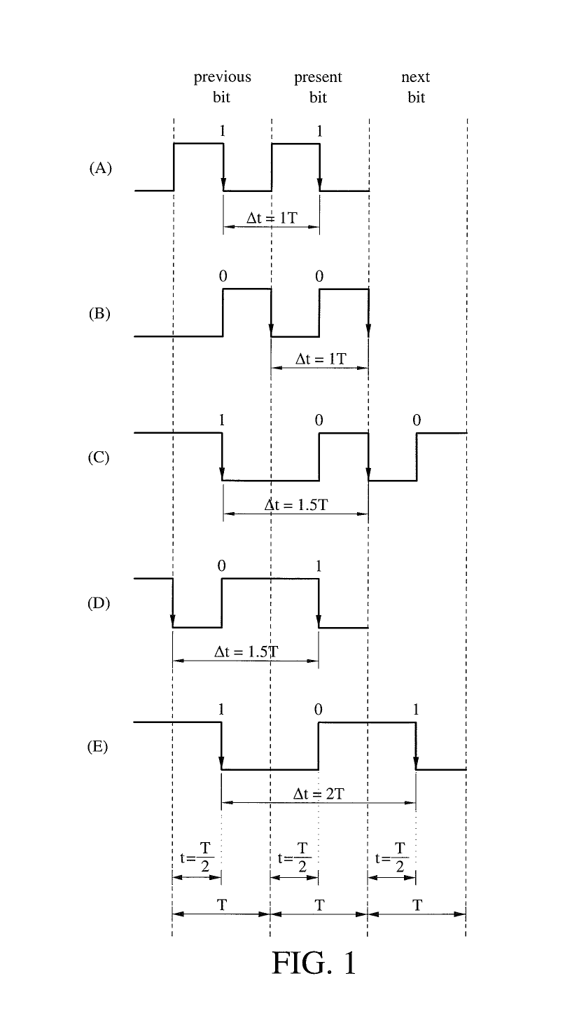

FIG. 1 is an exemplary diagram illustrating several partial waveforms of Manchester-encoded data. Referring to FIG. 1, the Manchester-encoded data has a plurality of bits, each of the bits has a bit period of T, and each of the bits has a transition at a time t=T/2 within its bit period T. In this embodiment, when one of the bits has a transition from a high level to a low level (i.e. a falling-edge transition) at the time t=T/2 within its bit period T, the logic value of the one of the bits is defined to be logic 1; and, when one of the bits has a transition from the low level to the high level (i.e. a rising-edge transition) at the time t=T/2 within its bit period T, the logic value of the one of the bits is defined to be logic 0.

Because of the characteristic of the Manchester encoding, a time difference (Δt) between two adjacent falling-edge transitions and the logic value of a previous bit have the following relations:
(A) when the time difference is 1 bit period (i.e. Δt=1T) and the logic value of a previous bit is logic 1, the logic value of a present bit is certainly logic 1;
(B) when the time difference is 1 bit period (i.e. Δt=1T) and the logic value of a previous bit is logic 0, the logic value of a present bit is certainly logic 0;
(C) when the time difference is 1.5 bit period (i.e. Δt=1.5T) and the logic value of a previous bit is logic 1, the logic values of a present bit and a next bit are certainly both certainly logic 0;
(D) when the time difference is 1.5 bit period (i.e. Δt=1.5T) and the logic value of a previous bit is logic 0, the logic value of a present bit is certainly logic 1;
(E) when the time difference is 2 bit period (i.e. Δt=2T) and the logic value of a previous bit is logic 1, the logic values of a present bit and a next bit are certainly logic 0 and logic 1, respectively.
   It is noted that the present bit is a bit which is being decoded in the decoding process of the Manchester-encoded data. The aforementioned relations may be shown in Table 1.

TABLE 1

| | The time difference (Δt) | | |
|---|---|---|---|
| | between two adjacent | | |
| | falling-edge transitions | | |
| | 1T | 1.5T | 2T |
| The logic value(s) of the present bit (or | 1 | 00 | 01 |
| the present and the next bits) when the | (A) | (C) | (E) |
| logic value of the previous bit is logic 1 | | | |
| The logic value of the present bit when the | 0 | 1 | N/A |
| logic value of the previous bit is logic 0 | (B) | (D) | |

Therefore, when the logic value of a first bit of the bits of the Manchester-encoded data is known, the logic values of the other bits of the bits of the Manchester-encoded data may be decoded by detecting falling-edge transitions in the Manchester-encoded data to decode according to the time difference Δt between each two adjacent falling-edge transitions and the logic value of the previous bit.

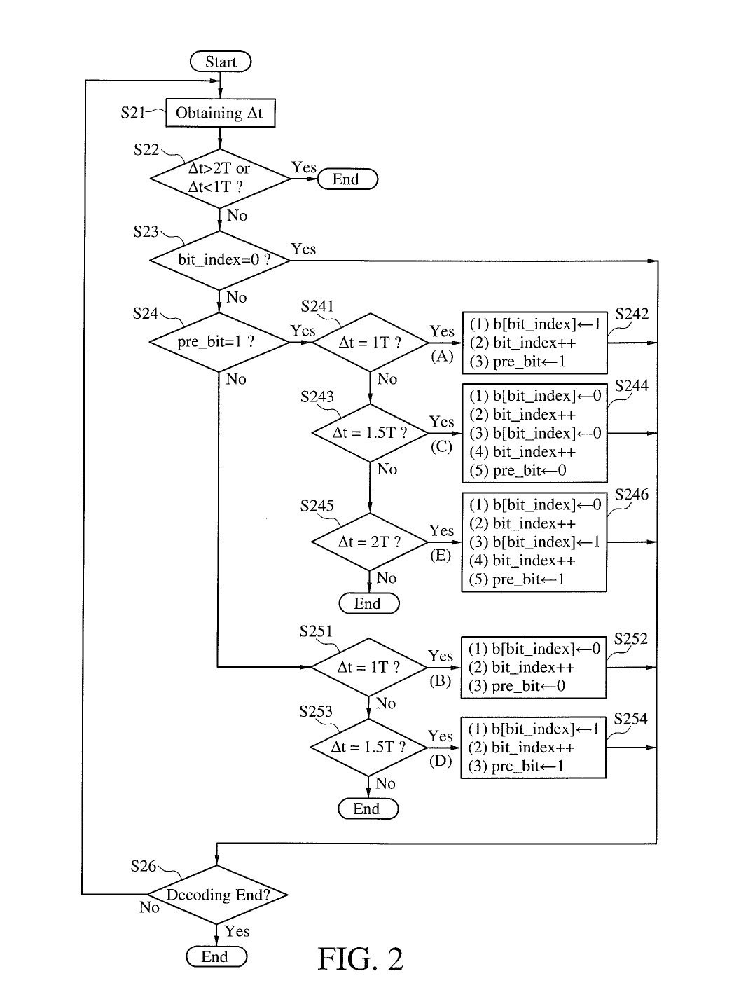

FIG. 2 is a flowchart illustrating a decoding method for Manchester-encoded data according to an embodiment of the present invention. Referring to FIG. 2, the Manchester-encoded data has N bits consisting of a first bit, a second bit, . . . , and a N-th bit, where N is an positive integer. For clarity of illustration, let b[0], b[1], . . . , and b[N−1] denote the first bit, the second bit, . . . , and the N-th bit respectively. Let Δt denote a time difference between two adjacent falling-edge transitions (hereinafter called the time difference Δt). Let bit_index denote a bit number indicating a bit position in the bits of the Manchester-encoded data. Let pre_bit denote the logic value of a previous bit.

At a step S21, a processor's interrupt pin is used to receive the bits of the Manchester-encoded data. When receiving the falling-edge transition in the Manchester-encoded data each time, the processor is interrupted to execute a falling-edge interrupt service routine to obtain a time difference between the previous interrupt and the present interrupt (i.e. the time difference Δt) so as to decode the present bit (or the present and the next bits) according to the previous bit value. When executing the falling-edge interrupt service routine at the first time (hereinafter called the first falling-edge interrupt service), the processor initializes variables such as Δt and bit_index, but does not start to decode because the time difference Δt is not yet generated during the first falling-edge interrupt service. After the first falling-edge interrupt service, the processor may obtain the time difference Δt when any falling-edge interrupt service occurs.

At a step S22, the processor determines whether the time difference Δt is greater than 2T or less than 1T. If the time difference Δt is greater than 2T or less than 1T, the time difference Δt is an invalid value so that the decoding process ends. If the time difference Δt is between 1T and 2T, the time difference Δt is a valid value so that the decoding process goes to a step S23.

At the step S23, the processor determines whether the bit number bit_index is equal to 0. If the bit number bit_index is equal to 0 (i.e. bit_index=0), it represents that the first bit b[0] is being decoded. However, because the logic value of the first bit b[0] is known (in the embodiment, is logic 1), the first bit b[0] does not have to be decoded so that the decoding process goes to a step S26. If the bit number bit_index is not equal to 0, it represents that the second bit b[1], the third bit b[2], . . . , or the N-th bit b[N−1] is being decoded so that the decoding process goes to a step S24. It is assumed that the present bit b[i] is being decoded, where i is 1, 2, . . . , or (N−1), and b[i−1] denotes the previous bit with respect to the present bit b[i], and b[i+1] denotes the next bit with respect to the present bit b[i].

At the step S24, the processor determines whether the logic value of the previous bit b[i−1] is logic 1. If the logic value of the previous bit b[i−1] is logic 1 (i.e. pre_bit=1), the processor may determine the logic value of the present bit b[i] or the logic values of the present bit b[i] and the next bit b[i+1] according to the relation (A), (C) or (E) shown in Table 1 so that the decoding process goes to a step S241. If the logic value of the previous bit b[i−1] is logic 0 (i.e. pre_bit=0), the processor may determine the logic value of the present bit b[i] according to the relation (B) or (D) shown in Table 1 so that the decoding process goes to a step S251.

At the step S241, the processor determines whether the time difference Δt is equal to 1T. If the time difference Δt is equal to 1T, it satisfies the conditions of the relation (A) shown in Table 1 so that the decoding process goes to a step S242. At the step S242, the processor sequentially executes the following sub-steps:
(1) b[bit_index]←1: setting the logic value of the present bit b[i] to be logic 1;
(2) bit_index++: increasing the bit number bit_index by 1 to make b[bit_index] now denote the next bit b[i+1]; and then necessarily determining whether new bit number bit_index is greater than (N−1) (i.e. the next bit b[i+1] does not belong to the first to the N-th bits b[0]˜b[N−1]); in which if yes, it represents that the decoding has completed so that the decoding process goes to the step S26, and if no, it represents that the decoding process does not end;
(3) pre_bit←1: if the decoding process does not end, setting pre_bit to be the same as the logic value of the present bit b[i] to be logic 1, and then the decoding process goes to the step S26.

At a step S243, the processor determines whether the time difference Δt is equal to 1.5T. If the time difference Δt is equal to 1.5T, it satisfies the conditions of the relation (C) shown in Table 1 so that the decoding process goes to a step S244. At the step S244, the processor sequentially executes the following sub-steps:
(1) b[bit_index]←0: setting the logic value of the present bit b[i] to be logic 0;
(2) bit_index++: increasing the bit number bit_index by 1 to make b[bit_index] now denote the next bit b[i+1]; and then necessarily determining whether new bit number bit_index is greater than (N−1) (i.e. the next bit b[i+1] does not belong to the first to the N-th bits b[0]˜b[N−1]); in which if yes, it represents that the decoding has completed so that the decoding process goes to the step S26, and if no, it represents that the decoding process does not end;
(3) b[bit_index]←0: if the decoding process does not end, setting the logic value of the next bit b[i+1] to be logic 0;
(4) bit_index++: increasing the bit number bit_index by 1 to make b[bit_index] now denote the next and next bit b[i+2]; and then necessarily determining whether new bit number bit_index is greater than (N−1) (i.e. the next and next bit b[i+2] does not belong to the first to the N-th bits b[0]˜b[N−1]); in which if yes, it represents that the decoding has completed so that the decoding process goes to the step S26, and if no, it represents that the decoding process does not end;
(5) pre_bit←0: if the decoding process does not end, setting pre_bit to be the same as the logic value of the next bit b[i+1] to be logic 0, and then the decoding process goes to the step S26.

At a step S245, the processor determines whether the time difference Δt is equal to 2T. If the time difference Δt is equal to 2T, it satisfies the conditions of the relation (E) shown in Table 1 so that the decoding process goes to a step S246. At the step S246, the processor sequentially executes the following sub-steps:
(1) b[bit_index]←0: setting the logic value of the present bit b[i] to be logic 0;
(2) bit_index++: increasing the bit number bit_index by 1 to make b[bit_index] now denote the next bit b[i+1];
(3) b[bit_index]←1: setting the logic value of the next bit b[i+1] to be logic 1;
(4) bit_index++: increasing the bit number bit_index by 1 to make b[bit_index] now denote the next and next bit b[i+2]; and then necessarily determining whether new bit number bit_index is greater than (N−1) (i.e. the next and next bit b[i+2] does not belong to the first to the N-th bits b[0]˜b[N−1]); in which if yes, it represents that the decoding has completed so that the decoding process goes to the step S26, and if no, it represents that the decoding process does not end;
(5) pre_bit←1: if the decoding process does not end, setting pre_bit to be the same as the logic value of the next bit b[i+1] to be logic 1, and then the decoding process goes to the step S26.

At the step S251, the processor determines whether the time difference Δt is equal to 1T. If the time difference Δt is equal to 1T, it satisfies the conditions of the relation (B) shown in Table 1 so that the decoding process goes to a step S252. At the step S252, the processor sequentially executes the following sub-steps:
(1) b[bit_index]←0: setting the logic value of the present bit b[i] to be logic 0;
(2) bit_index++: increasing the bit number bit_index by 1 to make b[bit_index] now denote the next bit b[i+1]; and then necessarily determining whether new bit number bit_index is greater than (N−1) (i.e. the next bit b[i+1] does not belong to the first to the N-th bits b[0]˜b[N−1]); in which if yes, it represents that the decoding has completed so that the decoding process goes to the step S26, and if no, it represents that the decoding process does not end;
(3) pre_bit←0: if the decoding process does not end, setting pre_bit to be the same as the logic value of the present bit b[i] to be logic 0, and then the decoding process goes to the step S26.

At a step S253, the processor determines whether the time difference Δt is equal to 1.5T. If the time difference Δt is equal to 1.5T, it satisfies the conditions of the relation (D) shown in Table 1 so that the decoding process goes to a step S254. At the step S254, the processor sequentially executes the following sub-steps:
(1) b[bit_index]←1: setting the logic value of the present bit b[i] to be logic 1;
(2) bit_index++: increasing the bit number bit_index by 1 to make b[bit_index] now denote the next bit b[i+1]; and then necessarily determining whether new bit number bit_index is greater than (N−1) (i.e. the next bit b[i+1] does not belong to the first to the N-th bits b[0]˜b[N−1]); in which if yes, it represents that the decoding has completed so that the decoding process goes to the step S26, and if no, it represents that the decoding process does not end;
(3) pre_bit←1: if the decoding process does not end, setting pre_bit to be the same as the logic value of the present bit b[i] to be logic 1, and then the decoding process goes to the step S26.

At the step S26, the processor determines whether the decoding has completed. If the decoding has completed, the decoding process ends. If the decoding is not yet completed, the decoding process goes back to the step S21.

It is noted that although the processor determines whether the time difference Δt is equal to 1T at the step S241 shown in FIG. 2, those skilled in the art should know that in practice it only needs to design the processor to determine whether the time difference Δt is equal to (1T±ΔT) in order to provide the acceptable tolerance ΔT without significantly affecting functioning of the decoding process. Similarly, in practice it only needs to design the processor to determine whether the time difference Δt is equal to (1.5T±ΔT), (2T±ΔT), (1T±ΔT) or (1.5T±ΔT) at the step S243, S245, S251 or S253 shown in FIG. 2.

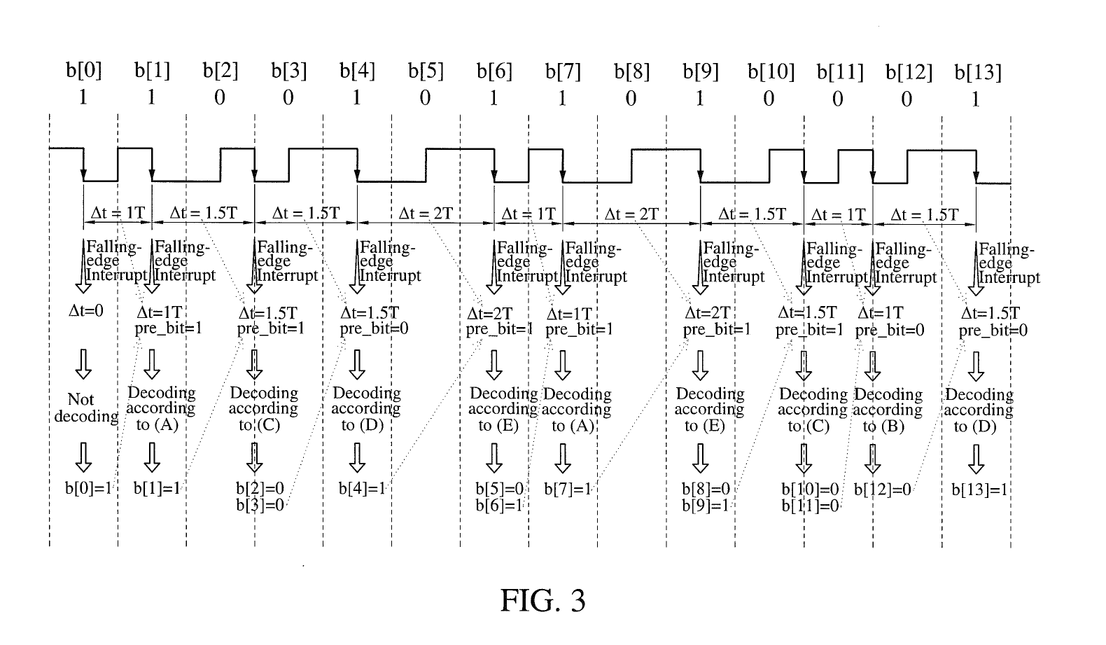

FIG. 3 is an exemplary diagram illustrating the decoding process of the Manchester-encoded data using the decoding method shown in FIG. 2. Referring to FIG. 2 and FIG. 3, the Manchester-encoded data shown in FIG. 3 is remote control encoded data using the RC-5 protocol or the extended RC-5 protocol. The Manchester-encoded data has 14 bits b[0]˜b[13]. Taking the fourth and the fifth falling-edge interrupts as examples, during the fourth falling-edge interrupt service, at first the bit number bit_index is 4, and the logic value of the previous bit b[3] is logic 0 (i.e. pre_bit=0). Then, at the step S21, the processor obtains the time difference Δt=1.5T. Because pre_bit=0 and Δt=1.5T, the decoding process goes through the steps S24, S251, S253 and S254. At the step S254, according to the relation (D) shown in Table 1, the processor sets the logic value of the present bit b[4] to be logic 1, and then increases the bit number bit_index by 1 to make bit_index become 5 and sets pre_bit to be the same as the logic value of the present bit b[4] to be logic 1, so that during the fifth falling-edge interrupt service, at first the bit number bit_index will be 5, and now the logic value of the previous bit b[4] is logic 1 (i.e. pre_bit=1).

During the fifth falling-edge interrupt service, at first the bit number bit_index is 5, and the logic value of the previous bit b[4] is logic 1 (i.e. pre_bit=1). Then, at the step S21, the processor obtains the time difference Δt=2T. Because pre_bit=1 and Δt=2T, the decoding process goes through the steps S24, S241, S243, S245 and S256. At the step S256, according to the relation (E) shown in Table 1, the processor sets the logic values of the present bit b[5] and the next bit b[6] to be logic 0 and logic 1, respectively, and then increases the bit number bit_index by 1 twice to make bit_index become 7 and sets pre_bit to be the same as the logic value of the next bit b[6] to be logic 1, so that during the sixth falling-edge interrupt service, at first the bit number bit_index will be 7, and now the logic value of the previous bit b[6] is logic 1 (i.e. pre_bit=1).

In summary, the present invention detects specific transitions (e.g. falling-edge transitions) in the biphase-encoded data (e.g. the Manchester-encoded data) to decode the biphase-encoded data according to a time difference between each two adjacent falling-edge transitions and the logic value of previous bit so that it uses no additional decoder chip, occupies less system resources, has good anti-interference and reduces the difficulty in software implementation.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

I claim:

1. A decoding method for biphase-encoded data having a plurality of bits wherein the logic value of a first bit of the bits is known, the logic value of one of the bits is a first logic value when the one of the bits has a transition from a first level to a second level at a time within a bit period, and the logic value of one of the bits is a second logic value when the one of the bits has a transition from the second level to the first level at the time within the bit period, the decoding method comprising:
detecting specific transitions in the biphase-encoded data to obtain a time difference between each two adjacent specific transitions;
when the time difference is 1 bit period and the logic value of a previous bit is the first logic value, determining that the logic value of a present bit is the first logic value;
when the time difference is 1 bit period and the logic value of a previous bit is the second logic value, determining that the logic value of a present bit is the second logic value;
when the time difference is 1.5 bit periods and the logic value of a previous bit is the first logic value, determining that the logic values of a present bit and a next bit are both the second logic value;
when the time difference is 1.5 bit periods and the logic value of a previous bit is the second logic value, determining that the logic value of a present bit is the first logic value; and
when the time difference is 2 bit periods and the logic value of a previous bit is the first logic value, determining that the logic values of a present bit and a next bit are the second logic value and the first logic value, respectively.

2. The decoding method according to claim 1, wherein the biphase-encoded data is Manchester-encoded data.

3. The decoding method according to claim 1, wherein the first level is a high level and the second level is a low level.

4. The decoding method according to claim 1, wherein the first level is a low level and the second level is a high level.

5. The decoding method according to claim 1, wherein the first logic value is logic 1 and the second logic value is logic 0.

6. The decoding method according to claim 1, wherein the first logic value is logic 0 and the second logic value is logic 1.

7. The decoding method according to claim 1, wherein the specific transition is the transition from the first level to the second level.

8. The decoding method according to claim 1, wherein the specific transition is the transition from the second level to the first level.

9. The decoding method according to claim 1, wherein the biphase-encoded data is applied to remote control encoded data using an RC-5 protocol.

10. The decoding method according to claim 1, wherein the biphase-encoded data is applied to remote control encoded data using an extended RC-5 protocol.
